(19) United States
(12) Patent Application Publication
(10) Pub. No.: US 2012/0234392 A1
(43) Pub. Date: Sep. 20, 2012

(54) PHOTOELECTRIC CONVERSION DEVICE

(75) Inventors: Yoshinobu Asami, Isehara (JP); Shunpei Yamazaki, Tokyo (JP)

(73) Assignee: SEMICONDUCTOR ENERGY LABORATORY CO., LTD., Atsugi-shi (JP)

(21) Appl. No.: 13/410,453

(22) Filed: Mar. 2, 2012

(30) Foreign Application Priority Data
Mar. 17, 2011 (JP) 2011-058821

(51) Int. Cl. H01L 31/0256; H01L 51/46; H01L 31/18

(52) U.S. Cl. 136/262; 438/85; 136/263; 257/E31.124

(57) ABSTRACT

A photoelectric conversion device with high open-circuit voltage and high conversion efficiency is provided. A photoelectric conversion device including a p-n junction is formed by stacking a first semiconductor layer having p-type conductivity, a second semiconductor layer having p-type conductivity, and a third semiconductor layer having n-type conductivity between a pair of electrodes. The first semiconductor layer is a compound semiconductor layer, and the second semiconductor layer is formed using an organic compound and an inorganic compound. A material having a high hole-transport property is used as the organic compound, and a transition metal oxide having an electron-accepting property is used as the inorganic compound.

### BACKGROUND OF THE INVENTION

1. Field of the Invention

The present invention relates to a photoelectric conversion device including a semiconductor layer formed using an organic compound and an inorganic compound.

2. Description of the Related Art

In recent years, a photoelectric conversion device that generates power without carbon dioxide emissions has attracted attention as a countermeasure against global warming. A bulk solar cell using a single crystal semiconductor substrate or the like is well known as a typical example of such a photoelectric conversion device, whereas a thin film solar cell which is advantageous in terms of manufacturing cost has also attracted attention.

Among thin film solar cells, expectations are placed on a solar cell including a compound semiconductor, such as CuInSe₂ (hereinafter referred to as CIS) or Cu(In,Ga)Se₂ (hereinafter referred to as CIGS), as a high-performance and inexpensive solar cell because it is free from light deterioration and has higher conversion efficiency than a solar cell including amorphous silicon.

In particular, a solar cell including CIGS is expected to have high conversion efficiency, because the band gap of CIGS can be controlled by changing the concentration of Ga as described in Non-Patent Document 1. In theory, the maximum conversion efficiency of a p-n junction solar cell is said to be obtained when the band gap is set in the range of 1.4 eV to 1.5 eV, in consideration of consistency with a solar spectrum. These values are included in a control range of the band gap of CIGS.

### REFERENCE

### Non-Patent Document

[Non-Patent Document 1] S. B. Zhang, Su-Huai Wei, and Alex Zunger, “A phenomenological model for systematization and prediction of doping limits in II-VI and I-III-VI₂ compounds”, J. Appl. Phys., Vol. 83, No. 6, 15 Mar. 1998.

### SUMMARY OF THE INVENTION

However, in current CIGS-based photoelectric conversion devices, the conversion efficiency becomes highest when the band gap is set to about 1.2 eV to 1.3 eV and is decreased when the band gap is widened to about 1.4 eV, contrary to the theory.

It is said that this is because the conduction band offset (ΔEc) becomes negative at a p-n junction interface and thereby the conduction band becomes discontinuous when the band gap of CIGS is widened. Specifically, the conduction band between CIGS (p-type) serving as a light absorption layer and a buffer layer (n-type) has a cliff shape; thus, photocarriers are easily recombined with each other and the open-circuit voltage is decreased. Accordingly, even when the band gap of CIGS is widened to about 1.4 eV, an increase in open-circuit voltage cannot be expected, resulting in decreased conversion efficiency.

In view of the above problem, an object of one embodiment of the present invention is to provide a photoelectric conversion device in which a semiconductor layer whose band gap is widened can be used as a light absorption layer without a decrease in open-circuit voltage.

One embodiment of the present invention disclosed in this specification relates to a photoelectric conversion device including a p-type semiconductor layer which is formed using an organic compound and an inorganic compound.

One embodiment of the present invention disclosed in this specification is a photoelectric conversion device including, between a pair of electrodes, a first semiconductor layer having p-type conductivity, a second semiconductor layer having p-type conductivity in contact with the first semiconductor layer, a third semiconductor layer having n-type conductivity in contact with the second semiconductor layer, and a light-transmitting conductive film in contact with the third semiconductor layer. The second semiconductor layer includes an organic compound and an inorganic compound.

Note that in this specification and the like, ordinal numbers such as “first” and “second” are used in order to avoid confusion among components, and do not limit the order or number of the components.

The first semiconductor layer includes a compound semiconductor represented by Cu(In₁₋ₓGaₓ)Se₂ (0≦x≦1, x is greater than or equal to 0 and less than or equal to 1), where x is preferably greater than or equal to 0.5 and less than or equal to 0.8.

As the inorganic compound, an oxide of a metal belonging to any of Groups 4 to 8 of the periodic table can be used. Specifically, an oxide of an element selected from V, Nb, Ta, Cr, Mo, W, Mn, and Re can be used, for example.

As the organic compound, any of an aromatic amine compound, a carbazole derivative, aromatic hydrocarbon, a high molecular compound, and a heterocyclic compound having a dibenzofuran skeleton or a dibenzothiophene skeleton can be used.

The third semiconductor layer preferably includes an oxide containing at least one element selected from Zn, Cd, Ga, In, Ag, Pb, Mg, Sn, Sb, Te, and Ge.

According to one embodiment of the present invention, a photoelectric conversion device in which the band gap of a light absorption layer can be widened without a decrease in open-circuit voltage and which has high conversion efficiency can be provided.

### BRIEF DESCRIPTION OF THE DRAWINGS

FIGS. 1A and 1B are cross-sectional views each illustrating a photoelectric conversion device according to one embodiment of the present invention.

FIG. 2 is a cross-sectional view illustrating a conventional photoelectric conversion device.

FIGS. 3A and 3B are band diagrams of a conventional photoelectric conversion device.

FIG. 4 is a band diagram of a photoelectric conversion device according to one embodiment of the present invention.

### DETAILED DESCRIPTION OF THE INVENTION

Hereinafter, embodiments of the present invention will be described in detail with reference to the accompanying drawings. Note that the present invention is not limited to the description below; and it is easily understood by those skilled in the art that modes and details disclosed herein can be modified in various ways. Therefore, the present invention is not construed as being limited to description of the embodiments. In the drawings for explaining the embodiments, the same portions or portions having similar functions are denoted by the same reference numerals, and description of such portions is not repeated in some cases.

### Embodiment 1

In this embodiment, a photoelectric conversion device according to one embodiment of the present invention and a manufacturing method thereof will be described.

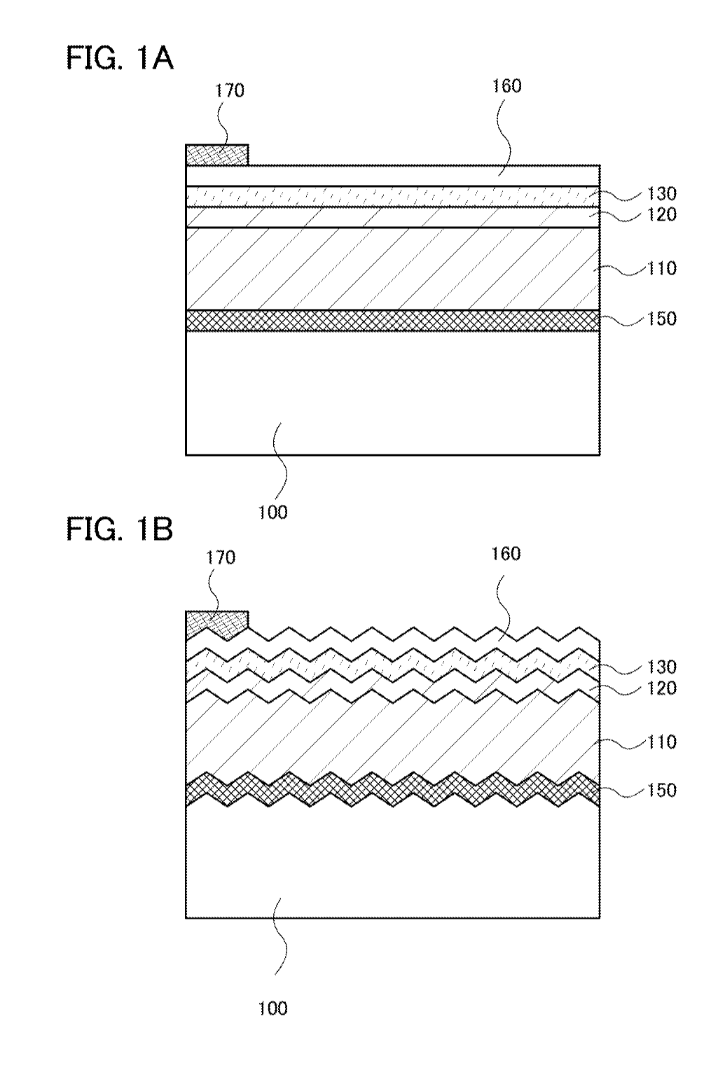

FIG. 1A is a cross-sectional view of a photoelectric conversion device according to one embodiment of the present invention, which includes a first electrode 150, a first semiconductor layer 110, a second semiconductor layer 120, a third semiconductor layer 130, a light-transmitting conductive film 160, and a second electrode 170 stacked in this order over a substrate 100. Note that in the photoelectric conversion device in FIG. 1A, a surface on the light-transmitting conductive film 160 side serves as a light-receiving surface; however, a surface on the substrate 100 side may serve as a light-receiving surface by reversing the order of stacking the layers over the substrate 100.

Alternatively, as illustrated in FIG. 1B, a surface of the substrate 100 may be uneven. By making the surface of the substrate 100 uneven, each interface between layers stacked thereover and a surface of the uppermost layer also become uneven. Owing to the unevenness, multiple reflections between surfaces of the layers, an increase in optical path length in a light absorption layer(the first semiconductor layer 110), and a total reflection effect (light-trapping effect) in which light reflected by a back electrode is totally reflected by a surface of the light absorption layer (the first semiconductor layer 110) are achieved, and electric characteristics of the photoelectric conversion device can be improved. Note that a surface of the first electrode 150 can be made uneven, instead of the surface of the substrate 100.

For the substrate 100, soda lime glass is preferably used, for example. In a CIGS-based (or CIS-based) photoelectric conversion device, defects of a light absorption layer can be repaired by diffusing Na thereinto, whereby electric characteristics can be improved. Therefore, soda lime glass which can serve as a diffusion source of Na is preferably used for the substrate.

Alternatively, a non-alkali glass substrate of aluminosilicate glass, barium borosilicate glass, aluminoborosilicate glass, or the like can be used as the substrate 100. In that case, temperatures at formation of the semiconductor layers and conductive films, which are formed over the substrate 100, can be increased and the qualities of these components can be improved, because the given glass substrates have higher heat resistance than soda lime glass. Note that in using any of the given glass substrates, it is preferable to perform a step of diffusing Na after formation of the light absorption layer (the first semiconductor layer 110).

For the first electrode 150, Au or Mo can be used. It is particularly preferable to use Mo, which can be easily formed into a low-density film, because the first electrode 150 also functions as a path through which Na is diffused from the substrate 100.

The first semiconductor layer 110 is a light absorption layer, and a p-type compound semiconductor which is represented by Cu(In₁₋ₓGaₓ)Se₂ (0≦x≦1. is greater than or equal to 0 and less than or equal to 1) is used therefor. An object of one embodiment of the present invention is to use a light absorption layer whose band gap is widened; thus, x is preferably set to a value greater than or equal to 0.5 and less than or equal to 0.8, in order to set the band gap of the light absorption layer to 1.4 eV to 1.5 eV.

The, second semiconductor layer 120 is a p-type junction forming layer for generation of an internal electric field, which comprises a composite material of an inorganic compound and an organic compound. As the inorganic compound, a transition metal oxide can be used; in particular, an oxide of a metal belonging to any of Groups 4 to 8 of the periodic table is preferable. Specifically, an oxide of an element selected from V, Nb, Ta, Cr, Mo, W, Mn, and Re can be used Among these, molybdenum oxide is particularly preferable because it is stable in the air, has a low hygroscopic property, and is easily handled.

As the organic compound, any of a variety of compounds such as an aromatic amine compound, a carbazole derivative, aromatic hydrocarbon, a high molecular compound (e.g., an oligomer, a dendrimer, or a polymer), and a heterocyclic compound having a dibenzofuran skeleton or a dibenzothiophene skeleton can be used. Note that the organic compound used for the composite material is preferably an organic compound having a high hole-transport property. Specifically, a substance having a hole mobility of 10⁻⁶ cm²/Vs or higher is preferably used. Note that any other substance may be used as long as the hole-transport property thereof is higher than the electron-transport property thereof.

The transition metal oxide has an electron-accepting property. A composite material of an organic compound having a high hole-transport property and such a transition metal oxide has high carrier density and exhibits p-type semiconductor characteristics. The composite material has a band gap Eg of about 3 eV and has high transmittance of light in a wide wavelength range from visible light region to infrared region.

The third semiconductor layer 130 is an n-type junction forming layer for generation of an internal electric field, and ZnO is preferably used therefor. Alternatively, ZnMgO, ZnGa₂O₄, Zn₂SnO₄, Zn₂In₂O₅, ZnSnO₃, CdO, CdIn₂O₄, CdGaO₄, Cd₂GeO₄, Cd₃TeO₆, CdSb₂O₇, Ga₂O₃, GaInO₃, CdSnO₃, In₂O₃, InGaMgO₄, InGaZnO₄, AgSbO₃, AgInO₂, PbO₂, MgIn₂O₄, CdO—GeO₂, In₂O₃—GaO₂—ZnO, In₂O₃—ZnO, or the like can be used.

For the light-transmitting conductive film 160, a material having a higher carrier concentration than the third semiconductor layer 130 is preferably used. For example, a material in which Al, B, Ga, or In is added to ZnO; Zn₂In₂O₅; ZnSnO₃; CdO; CdIn₂O₄; Cd₂SnO₄; CdSnO₃; Cd₃TeO₆; Cd₂Sb₂O₂; In₂O₃; SnO₂; PbO₂; GaInO₃; In₂O₃—ZnO; CdO—GeO₂; In₂O₃—SnO₂ (ITO); or the like can be used.

For the second electrode 170, a metal film of Al, Ti, Ag, Mo, Ta, W, Cr, Cu, or the like can be used. The metal film is not limited to a single layer, and different films may be laminated.

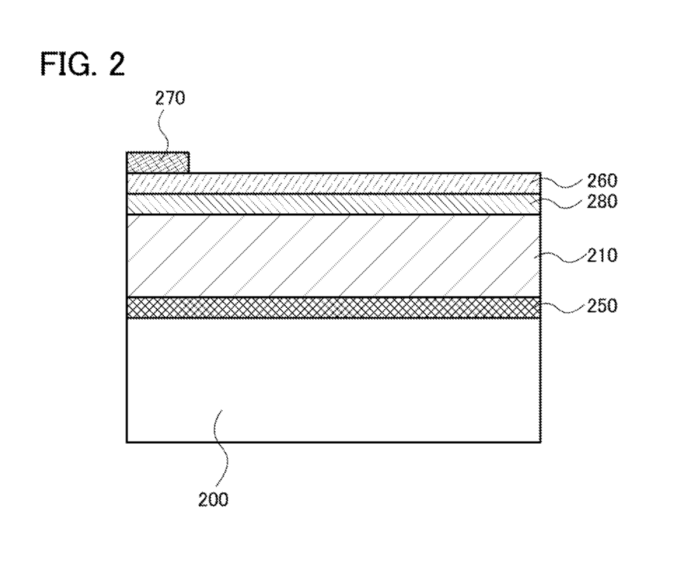

FIG. 2 is a cross-sectional view of a conventional CIGS-based (or CIS-based) photoelectric conversion device. A first electrode 250, a semiconductor layer 210, a buffer layer 280, a light-transmitting conductive film 260, and a second electrode 270 are stacked in this order over a substrate 200.

The materials which can be used for the first electrode 150 and the first semiconductor layer 110 can be used, respectively, for the first electrode 250 and the semiconductor layer 210. The materials which can be used for the light-transmitting conductive film 160 and the second electrode 170 can be used, respectively, for the light-transmitting conductive film 260 and the second electrode 270.

In the photoelectric conversion device in FIG. 2, a p-n junction is formed at an interface between the p-type semiconductor layer 210 (e.g., CIGS) and the buffer layer 280 which is an n-type semiconductor layer. For the buffer layer 280, any of CdS, ZnS, ZnS(O,OH), and the like, which have n-type conductivity, is used.

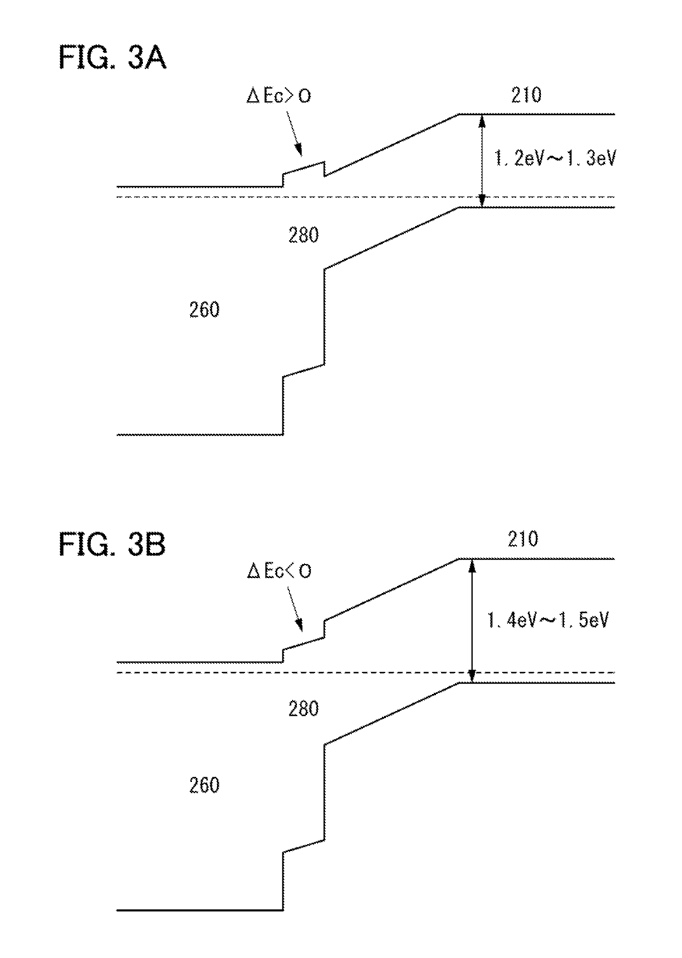

Here, a band structure in the vicinity of the p-n junction in the photoelectric conversion device in FIG. 2 will be described with reference to FIGS. 3A and 3B. FIG. 3A is a band diagram in the case where CIGS having a band gap of 1.2 eV to 1.3 eV, which is currently used, is used for the semiconductor layer 210. A p-n junction is formed between the semiconductor layer 210 and the buffer layer 280, but because there is a difference in electron affinity therebetween, the conduction band offset becomes positive (ΔEc>0) and a spike-shaped barrier is formed at the p-n junction portion. This barrier might cause a decrease in short-circuit current, but carrier transportation can be less affected by the barrier when the difference in electron affinity between the semiconductor layer 210 and the buffer layer 280 is small.

FIG. 3B is a band diagram in the case where CIGS having a band gap of 1.4 eV to 1.5 eV, which is theoretically expected to achieve high conversion efficiency, is used for the semiconductor layer 210. In this case, the conduction band offset becomes negative (ΔEc<0) and the conduction band has a cliff shape at a p-n junction portion. Thus, photocarriers remain in the vicinity of the junction interface so as to be easily recombined, so that the open-circuit voltage and the fill factor are decreased. Consequently, the conversion efficiency cannot be improved even when CIGS having a band gap of 1.4 eV to 1.5 eV, which is theoretically expected to achieve high conversion efficiency, is used for the semiconductor layer 210.

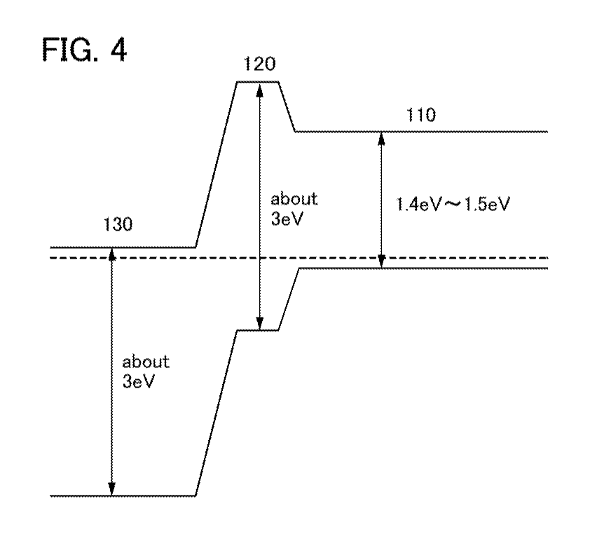

FIG. 4 shows a band structure of a photoelectric conversion device according to one embodiment of the present invention. A p-n junction of the photoelectric conversion device is formed between the p-type second semiconductor layer 120 and the n-type third semiconductor layer 130, each of which has a band gap of about 3 eV. The open-circuit voltage can be increased by widening the band gap of each material used for forming the p-n junction; thus, in the photoelectric conversion device in FIG. 4, the open-circuit voltage can be made higher than in the case of directly using CIGS for a layer for generation of an internal electric field in a p-n junction.

Although the p-type first semiconductor layer 110 which is a light absorption layer is connected to the second semiconductor layer 120, a barrier is formed therebetween because of a difference in the band gaps. Accordingly, the band gap of the first semiconductor layer 110 is preferably widened so that the barrier is lowered.

As described above, in a conventional CIGS-based or CIS-based) photoelectric conversion device, the band gap cannot be widened for the reason described with reference to FIG. 3B, whereas in the photoelectric conversion device of one embodiment of the present invention, CIGS having a band gap of 1.4 eV to 1.5 eV, which is theoretically expected to achieve high conversion efficiency, is desirably used.

The second semiconductor layer 120 can be formed to a thickness of greater than or equal to 1 nm and less than or equal to 30 nm. A thickness of greater than or equal to 1 nm and less than or equal to 10 nm is further preferable, because in that case, photoexcited carriers in the first semiconductor layer 110 can be transported to the third semiconductor layer 130 side owing to a quantum effect. Accordingly, even when a barrier is formed between the first semiconductor layer 110 and the second semiconductor layer 120, carrier transportation can substantially be less affected by the barrier.

As described above, in the photoelectric conversion device of one embodiment of the present invention, the open-circuit voltage can be increased without a decrease in photocurrent generated by photoexcited carriers, so that conversion efficiency can be improved.

Next, an example of a method for manufacturing the photoelectric conversion device in FIG. 1A will be described.

First, a conductive film serving as the first electrode 150 is formed over the substrate 100. Here, a 1-μm-thick Mo film is formed by a sputtering method.

Next, as the first semiconductor layer 110, Cu(In₁₋ₓGaₓ)Se₂ is deposited to a thickness of about 2 μm by a three-step evaporation method. In this embodiment, the Ga concentration is adjusted so that x is set to 0.6. First, (In,Ga)₂Se₃ is deposited over the first electrode 150 at a substrate temperature higher than or equal to 300° C. and lower than or equal to 400° C. Next, Cu and Se are deposited at a substrate temperature of 500° C. or higher, whereby Cu-excess Cu(In,Ga)Se₂ is obtained, and then, In, Ga, and Se are deposited at the same time. In this manner, the desired composition is obtained.

Next, the second semiconductor layer 120 is formed over the first semiconductor layer 110. The second semiconductor layer 120 is formed by co-deposition of the above-described inorganic compound and the above-described organic compound. Note that the co-evaporation is an evaporation method in which evaporation is performed simultaneously from a plurality of evaporation sources in one chamber. It is preferable that deposition be performed under high vacuum. Specifically, the deposition chamber is evacuated to a vacuum of 5×10⁻³ Pa or less, preferably about 10⁻⁴ Pa to 10⁻⁶ Pa.

In this embodiment, the second semiconductor layer 120 is formed by co-depositing 4-phenyl-4′-(9-phenylfluoren-9-yl)triphenylamine (abbreviation: BPAFLP) and molybdenum oxide. The thickness of the second semiconductor layer 120 is set to 10 nm, and the weight ratio of BPAFLP to molybdenum oxide is controlled to be 2:1 (=BPAFLP:molybdenum oxide).

Next, a 100-nm-thick ZnO film is formed as the third semiconductor layer 130 over the second semiconductor layer 120. The third semiconductor layer 130 may be formed by metal organic chemical vapor deposition (MOCVD) instead of a sputtering method.

Next, a 1-μm-thick film of a material in which Al is added to ZnO is formed by a sputtering method as the light-transmitting conductive film 160 over the third semiconductor layer 130. The light-transmitting conductive film 160 may be formed by MOCVD instead of a sputtering method. Although not shown in FIGS. 1A and 1B, an anti-reflective film may additionally be provided over the light-transmitting conductive film 160 in order to decrease the reflectance of its surface. As the anti-reflective film, a film of a low refractive index material such as MgF₂, SiO₂, or SiOₓN_{y} (x>y) can be formed by a sputtering method, an evaporation method, or the like.

Next, a conductive film with a thickness of 0.5 μm to 10 μis formed as the second electrode 170 over the light-transmitting conductive film 160. Here, a 1-μm-thick Al film is formed by a sputtering method.

Through the above process, the photoelectric conversion device according to one embodiment of the present invention can be manufactured. Note that in this embodiment, a manufacturing method of a single cell structure which is illustrated as an example in FIGS. 1A and 1B is described; however, an integrated structure in which a plurality of cells are connected in series can also be formed by using a scribing process or the like in combination with the manufacturing method.

This embodiment can be implemented in appropriate combination with any of the structures described in the other embodiment.

### Embodiment 2

In this embodiment, the second semiconductor layer described in Embodiment 1 will be described.

For the second semiconductor layer 120 in the photoelectric conversion device described in Embodiment 1, a composite material of a transition metal oxide and an organic compound can be used. Note that in this specification, the word “composite” means not only a state in which two materials are simply mixed but also a state in which a plurality of materials is mixed and charges are transferred between the materials.

As the transition metal oxide, a transition metal oxide having an electron-accepting property can be used. Specifically, among transition metal oxides, an oxide of a metal belonging to any of Groups 4 to 8 of the periodic table, is preferable. In particular, an oxide of any of V, Nb, Ta, Cr, Mo, W, Mn, and Re is preferable because of having a high electron-accepting property. Among these, molybdenum oxide is particularly preferable because it is stable in the air, has a low hygroscopic property, and is easily handled.

As the organic compound, any of a variety of compounds such as an aromatic amine compound, a carbazole derivative, an aromatic hydrocarbon, a high molecular compound (e.g., an oligomer, a dendrimer, or a polymer), and a heterocyclic compound having a dibenzofuran skeleton or a dibenzothiophene skeleton can be used. Note that the organic compound used for the composite material is preferably an organic compound having a, high hole-transport property. Specifically, a substance having a hole, mobility of 10⁻⁶ cm²/Vs or higher is preferably used. Note that any other substance may be used as long as the hole-transport property thereof is higher than the electron-transport property thereof.

In a composite material of the above-described transition metal oxide and the above-described organic compound, electrons in the highest occupied molecular orbital level (HOMO level) of the organic compound are transferred to the conduction band of the transition metal oxide, whereby interaction between the transition metal oxide and the organic compound occurs. Due to this interaction, the composite material including the transition metal oxide and the organic compound has high carrier density and has p-type semiconductor characteristics.

The organic compounds which can be used for the composite material will be specifically shown below.

As the aromatic amine compound that can be used for the composite material, following can be given as examples: 4,4′-bis[N-(1-naphthyl)-N-phenylamino]biphenyl (abbreviation: NPB); N,N′-bis(3-methylphenyl)-N,N′-diphenyl-[1,1′-biphenyl]-4,4′-diamine (abbreviation: TPD); 4,4′,4″-tris(N,N-diphenylamino)triphenylamine (abbreviation: TDATA); 4,4′,4″-tris[N-(3-methylphenyl)-N-phenylamino]triphenylamine (abbreviation: MTDATA); and N,N′-bis(spiro-9,9′-bifluoren-2-yl)-N,N′-diphenylbenzidine (abbreviation: BSPB). In addition, the following can be given: N,N′-bis(4-methylphenyl)-N,N′-diphenyl-p-phenylenediamine (abbreviation: DTDPPA); 4,4′-bis[N-(4-diphenylaminophenyl)-N-phenylamino]biphenyl (abbreviation: DPAB); N,N′-bis[4-[bis(3-methylphenyl)amino]phenyl]-N,N′-diphenyl-[1,1′-biphenyl]-4,4′-diamine (abbreviation: DNTPD); 1,3,5-tris[N-(4-diphenylaminophenyl)-N-phenylamino]benzene (abbreviation: DPA3B); 4-phenyl-4′-(9-phenylfluoren-9-yl)triphenylamine (abbreviation: BPAFLP); and 4,4′-bis[N-(9,9-dimethylfluoren-2-yl)-N-phenylamino]biphenyl (abbreviation: DFLDPBi);.

As the carbazole derivative that can be used for the composite material, the following can be specifically given: 3-[N-(9-phenylcarbazol-3-yl)-N-phenylamino]-9-phenylcarbazole (abbreviation: PCzPCA1); 3,6s[N-(9-phenylcarbazol-3-yl)-N-phenylamino]-9-phenylcarbazole (abbreviation: PCzPCA2); and 3-[N-(1-naphthyl)-N-(9-phenylcarbazol-3-yl)amino]-9-phenylcarbazole (abbreviation: PCzPCN1).

As other examples of the carbazole derivative that can be used for the composite material, the following can be given: 4,4′-di(N-carbazolyl)biphenyl (abbreviation: CBP); 1,3,5-tris[4-(N-carbazolyl)phenyl]benzene (abbreviation: TCPB); 9-[4-(N-carbazolyl)phenyl]-10-phenylanthracene (abbreviation: CzPA); and 1,4-bis[4-(N-carbazolyl)phenyl]-2,3,5,6-tetraphenylbenzene.

As the aromatic hydrocarbon that can be used for the composite material, the following can be given, for example: 2-tert-butyl-9,10-di(2-naphthyl)anthracene (abbreviation: t-BuDNA); 2-tert-butyl-9,10-di(1-naphthyl)anthracene; 9,10-bis(3,5-diphenylphenyl)anthracene (abbreviation: DPPA); 2-tert-butyl-9,10-bis(4-phenylphenyl)anthracene (abbreviation: t-BuDBA); 9,10-di(2-naphthyl)anthracene (abbreviation: DNA); 9,10-diphenylanthracene (abbreviation: DPAnth); 2-tert-butylanthracene (abbreviation: t-BuAnth); 9,10-bis(4-methyl-1-naphthyl)anthracene (abbreviation: DMNA); 9,10-bis[2-(1-naphthyl)phenyl]-2-tert-butylanthracene; 9,10-bis[2-(1-naphthyl)phenyl]anthracene; 2,3,6,7-tetramethyl-9,10-di(1-naphthyl)anthracene; 2,3,6,7-tetramethyl-9,10-di(2-naphthyl)anthracene; 9,9′-bianthryl; 10,10′-diphenyl-9,9′-bianthryl; 10,10′-bis(2-phenylphenyl)-9,9′-bianthryl; 10,10′-bis[(2,3,4,5,6-pentaphenyl)phenyl]-9,9′-bianthryl; anthracene; tetracene; rubrene; perylene; and 2,5,8,11-tetra(tert-butyl)perylene. Besides, pentacene, coronene; or the like can also be used. It is particularly preferable to use the aromatic hydrocarbon which has a hole mobility of 1×10⁻⁶ cm²/Vs or higher and which has 14 to 42 carbon atoms.

The aromatic hydrocarbon used for the composite material may have a vinyl skeleton. As the aromatic hydrocarbon having a vinyl group, the following can be given, for example: 4,4′-bis(2,2-diphenylvinyl)biphenyl (abbreviation: DPVBi); and 9,10-bis[4-(2,2-diphenylvinyl)phenyl]anthracene(abbreviation: DPVPA).

The organic compound used for the composite material may be a heterocyclic compound having a dibenzofuran skeleton or a dibenzothiophene skeleton.

The Organic compound that can be used for the composite material may be a high molecular compound, and the following can be given as examples: poly(N-vinylcarbazole) (abbreviation: PVK); poly(4-vinyltriphenylamine) (abbreviation: PVTPA); poly[N-(4-{N′-[4-(4-diphenylamino)phenyl]phenyl-N′-phenylamino}phenyl)methacrylamide] (abbreviation: PTPDMA); and poly[N,N′-bis(4-butylphenyl)-N,N′-bis(phenyl)benzidine] (abbreviation: Poly-TPD).

The composite material described in this embodiment has a wide band gap and therefore has an excellent light-transmitting property with respect to light in a wavelength range light of which is absorbed by CIS or CIGS, which serves as a light absorption layer of a photoelectric conversion device. Accordingly, light is hardly lost owing to light absorption in the composite material, so that light can reach the light absorption layer efficiently.

A variety of methods can be used for forming the semiconductor layer, whether the method is a dry process or a wet process. As a dry method, a co-evaporation method, by which a plurality of evaporation materials is vaporized from a plurality of evaporation sources to perform deposition, and the like are given as examples. As a wet method, a composition having a composite material is adjusted by a sol-gel method or the like, and deposition can be performed using an ink-jet method or a spin-coating method.

This embodiment can be implemented in appropriate combination with any of the structures described in the other embodiment.

This application is based on Japanese Patent Application serial no. 2011-058821 filed with Japan Patent Office on Mar. 17, 2011, the entire contents of which are hereby incorporated by reference.

What is claimed is:

1. A photoelectric conversion device comprising:
a pair of electrodes;
a first semiconductor layer having p-type conductivity;
a second semiconductor layer having p-type conductivity in contact with the first semiconductor layer;
a third semiconductor layer having n-type conductivity in contact with the second semiconductor layer; and
a light-transmitting conductive film in contact with the third semiconductor layer,
wherein the first semiconductor layer, the second semiconductor layer, the third semiconductor layer and the light-transmitting conductive film are provided between the pair of electrodes, and
wherein the second semiconductor layer comprises a composite material, the composite material comprising an organic compound and an inorganic compound.

2. The photoelectric conversion device according to claim 1, wherein the inorganic compound is an oxide of a metal belonging to any of Groups 4to 8 of the periodic table.

3. The photoelectric conversion device according to claim 1, wherein the inorganic compound is an oxide of an element selected from V, Nb, Ta, Cr, Mo, W, Mn, and Re.

4. The photoelectric conversion device according to claim 1, wherein the organic compound is at least one selected from an aromatic amine compound, a carbazole derivative, an aromatic hydrocarbon, a high molecular compound, and a heterocyclic compound having a dibenzofuran skeleton or a dibenzothiophene skeleton.

5. The photoelectric conversion device according to claim 1, wherein the third semiconductor layer includes an oxide containing at least one element selected from Zn, Cd, Ga, In, Ag, Pb, Mg, Sn, Sb, Te, and Ge.

6. A photoelectric conversion device comprising:
a pair of electrodes;
a first semiconductor layer having p-type conductivity;
a second semiconductor layer having p-type conductivity in contact with the first semiconductor layer;
a third semiconductor layer having n-type conductivity in contact with the second semiconductor layer; and
a light-transmitting conductive film in contact with the third semiconductor layer,
wherein the first semiconductor layer comprises a compound semiconductor represented by Cu(In₁₋ₓGaₓ)Se₂ (0≦x≦1, x is greater than or equal to 0 and less than or equal to 1),
wherein the first semiconductor layer, the second semiconductor layer, the third semiconductor layer and the light-transmitting conductive film are provided between the pair of electrodes, and
wherein the second semiconductor layer comprises a composite material, the composite material comprising an organic compound and an inorganic compound.

7. The photoelectric conversion device according to claim 6, wherein the inorganic compound is an oxide of a metal belonging to any of Groups 4 to 8 of the periodic table.

8. The photoelectric conversion device according to claim 6, wherein the inorganic compound is an oxide of an element selected from V, Nb, Ta, Cr, Mo, W, Mn, and Re.

9. The photoelectric conversion device according to claim 6, wherein the organic compound is at least one selected from an aromatic amine compound, a carbazole derivative, an aromatic hydrocarbon, a high molecular compound, and a heterocyclic compound having a dibenzofuran skeleton or a dibenzothiophene skeleton.

10. The photoelectric conversion device according to claim 6, wherein the third semiconductor layer includes an oxide containing at least one element selected from Zn, Cd, Ga, In, Ag, Pb, Mg, Sn, Sb, Te, and Ge.

11. A method for manufacturing a photoelectric conversion device comprising the steps of:
forming a first electrode;
forming a first semiconductor layer having p-type conductivity over the first electrode;
forming a second semiconductor layer having p-:type conductivity over and in contact with the first semiconductor layer;
forming a third semiconductor layer having ti-type conductivity over and in contact with the second semiconductor layer;
forming a light-transmitting conductive film over and in contact with the third semiconductor layer; and
forming a second electrode over the light-transmitting conductive film, wherein the second semiconductor layer comprises a composite material, the composite material comprising an organic compound and an inorganic compound.

12. The method for manufacturing the photoelectric conversion device according to claim 11, wherein the first semiconductor layer comprises a compound semiconductor represented by Cu(In₁₋₁Gaₓ)Se₂ (0≦x≦1, x is greater than or equal to 0 and less than or equal to 1).

13. The method for manufacturing the photoelectric conversion device according to claim 12, wherein the first semiconductor layer is formed by an evaporation method.

14. The method for manufacturing the photoelectric conversion device according to claim 11, wherein the second semiconductor layer is formed by an evaporation method.

15. The method for manufacturing the photoelectric conversion device according to claim 11, wherein the inorganic compound is an oxide of a metal belonging to any of Groups 4 to 8 of the periodic table.

16. The method for manufacturing the photoelectric conversion device according to claim 11, wherein the inorganic compound is an oxide of an element selected from V, Nb, Ta, Cr, Mo, W, Mn, and Re.

17. The method for manufacturing the photoelectric conversion device according to claim 11, wherein the organic compound is at least one selected from an aromatic amine compound, a carbazole derivative, an aromatic hydrocarbon, a high molecular compound, and a heterocyclic compound having a dibenzofuran skeleton or a dibenzothiophene skeleton.

18. The method for manufacturing the photoelectric conversion device according to claim 11, wherein the third semiconductor layer includes an oxide, containing at least one element selected from Zn, Cd, Ga, In, Ag, Pb, Mg, Sn, Sb, Te, and Ge.
